(19) United States
(12) Patent Application Publication
(10) Pub. No.: US 2007/0052346 A1
(43) Pub. Date: Mar. 8, 2007

(54) Organic electroluminescence device

(75) Inventors: Toshihiro Iwakuma, Sodegaura-shi (JP); Masahide Matsuura, Sodegaura-shi (JP); Hideaki Nagashima, Sodegaura-shi (JP); Hidetsugu Ikeda, Sodegaura-shi (JP); Hiroaki Nakamura, Sodegaura-shi (JP); Tadashi Kusumoto, Sodegaura-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Idemitsu Kosan Co., Ltd., Chiyoda-ku (JP)

(21) Appl. No.: 11/480,465

(22) Filed: Jul. 5, 2006

(30) Foreign Application Priority Data
Sep. 8, 2005 (JP) 2005-260272

(51) Int. Cl. H01L 51/00

(52) U.S. Cl. 313/504

(57) ABSTRACT

An organic electroluminescent device (1) including an anode (2), a cathode (6), and at least a first layer (3), a second layer (4), and a third layer (5) provided between the anode (2) and the cathode (6). At least one of the first to third layers (3), (4), and (5) includes a phosphorescent compound, and at least one of the first to third layers (3), (4), and (5) is an emitting layer. Compounds respectively forming the first to third layers (3), (4), and (5) and having the largest ionization potentials of the respective layers have an ionization potential of 5.7 eV or more and differ in the ionization potential in an amount of less than 1.0 eV.

### BACKGROUND OF THE INVENTION

1. Field of the Invention

The invention relates to an organic electroluminescent device. In particular, the invention relates to a phosphorescent organic electroluminescent device.

2. Description of Related Art

An organic electroluminescent device (hereinafter called “organic EL device”) is driven at a low voltage and exhibits a high luminance and a wide viewing angle. Therefore, a display (organic EL display) including the organic EL device is expected to be applied to a wide range of applications.

The organic EL device includes an emitting layer provided between a pair of opposing electrodes. When an electric field is applied between the electrodes of the organic EL device, electrons are injected from the cathode and holes are injected from the anode. The electrons and the holes recombine in the emitting layer to produce an excited state, and the energy is emitted as light when the excited state returns to the ground state.

As the device configuration of the organic EL device, a configuration including anode/hole transporting layer/emitting layer/electron transporting layer/cathode has been known (patent documents 1 to 4 and non-patent document 1). The hole transporting layer assists in transporting holes from the anode to the emitting layer, and the electron transporting layer assists in transporting electrons from the cathode to the emitting layer.

[Patent document 1] WO 01/93642

[Patent document 2] WO 02/15645

[Patent document 3] US-A-2002-0034656

[Patent document 4] US-A-2002-0113545

[Non-patent document 1] J. Appl. Phys. 2001, 90, 5048

However, the devices disclosed in the patent documents 1 to 4 and the non-patent document 1 are green organic EL devices with a small energy level. When forming a blue organic EL device, since the energy gap of the compound forming each layer is small, excitons are deactivated. Moreover, the luminous efficiency decreases due to Förster energy transfer to a layer other than the emitting layer.

An object of the invention is to provide an organic EL device which exhibits a high energy level and a high luminous efficiency.

### SUMMARY OF THE INVENTION

According to the invention, the following organic EL device is provided.

1. An organic electroluminescent device comprising:

an anode, a cathode, and at least a first layer, a second layer, and a third layer provided between the anode and the cathode;

at least one of the first to third layers including a phosphorescent compound, at least one of the first to third layers being an emitting layer, and compounds respectively forming the first to third layers and having the largest ionization potentials of the respective layers having an ionization potential of 5.7 eV or more and differing in the ionization potential in an amount of less than 1.0 eV.

2. The organic electroluminescent device according to 1, wherein the compounds having the largest ionization potentials of the respective layers are compounds other than the phosphorescent compound.

3. The organic electroluminescent device according to 1, wherein at least one of the first to third layers is the emitting layer, and at least one emitting layer includes the phosphorescent compound.

4. The organic electroluminescent device according to 1, wherein the second layer is the emitting layer, and the emitting layer includes the phosphorescent compound.

5. The organic electroluminescent device according to any one of 1 to 4, wherein the difference in the ionization potential is less than 0.6 eV.

6. The organic electroluminescent device according to any one of 1 to 5, wherein at least two of a first compound forming the first layer, a second compound forming the second layer, and a third compound forming the third layer are compounds other than the phosphorescent compound and have a singlet energy level of 3.3 eV or more.

7. The organic electroluminescent device according to any one of 1 to 5, wherein at least two of a first compound forming the first layer, a second compound forming the second layer, and a third compound forming the third layer are compounds other than the phosphorescent compound and have a lowest triplet energy level of 2.7 eV or more.

8. The organic electroluminescent device according to any one of 1 to 7, wherein the phosphorescent compound has a lowest triplet energy level of 2.4 eV or more.

9. The organic electroluminescent device according to 4, wherein the first layer and the third layer contact the emitting layer including the phosphorescent compound.

10. The organic electroluminescent device according to any one of 1 to 9, wherein the phosphorescent compound is a heavy metal complex.

According to the invention, a highly efficient organic EL device can be provided. In particular, the invention is effective for a blue device with a high energy level so that a device can be realized which is driven at a low voltage and exhibits a high efficiency and a long lifetime.

### BRIEF DESCRIPTION OF THE DRAWINGS

FIG. 1 is a cross-sectional view showing an embodiment of an organic EL device according to the invention.

FIGS. 2(a) to 2(c) are views showing examples of the energy levels of compounds forming a first layer 3, a second layer 4, and a third layer 5 shown in FIG. 1.

### BEST MODE FOR CARRYING OUT THE INVENTION

An organic EL device according to the invention includes an anode, a cathode, and at least a first layer, a second layer, and a third layer provided between the anode and the cathode.

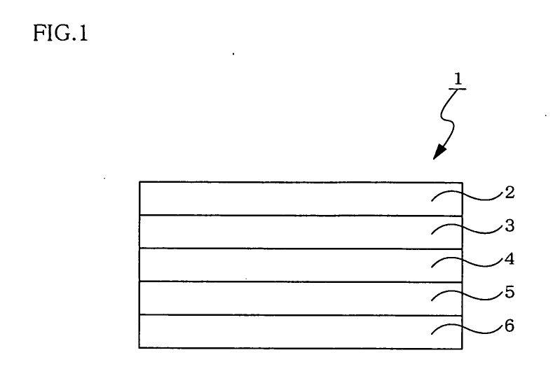

FIG. 1 is a view showing a configuration of an organic EL device according to one embodiment of the invention.

As shown in FIG. 1, an organic EL device 1 has a structure in which an anode 2, a first layer 3, a second layer 4, a third layer 5, and a cathode 6 are stacked.

At least one of the first layer 3, the second layer 4, and the third layer 5 includes a phosphorescent compound.

At least one of the first layer 3, the second layer 4, and the third layer 5 is an emitting layer. For example, one of the first layer 3, the second layer 4, and the third layer 5 may be an emitting layer. It is preferable that the second layer 4 be an emitting layer, and the emitting layer include a phosphorescent compound. Two or more of the first layer 3, the second layer 4, and the third layer 5 may be emitting layers. When a plurality of emitting layers are provided, it is preferable that at least one emitting layer include a phosphorescent compound.

As shown in FIG. 1, the first layer 3 and the third layer 5 preferably contact the second layer 4. Note that an intermediate layer may be provided between the first layer 3 and the second layer 4 or between the third layer 5 and the second layer 4.

When the first layer 3, the second layer 4, or the third layer 5 is not an emitting layer, the first layer 3 and/or the second layer 4 on the anode 2 side may be a layer with a hole transporting property such as a hole injecting layer or a hole transporting layer, and the second layer 4 and/or the third layer 5 on the cathode 6 side may be a layer with an electron transporting property such as an electron injecting layer or electron transporting layer.

The hole transporting layer, electron transporting layer, and emitting layer may include a phosphorescent compound.

In the invention, among compounds respectively forming the first layer 3, the second layer 4, and the third layer 5, compounds having the largest ionization potentials of the respective layers have an ionization potential of 5.7 eV or more, and differ in the ionization potential in an amount of less than 1.0 eV. The compounds having the largest ionization potentials of the respective layers may be a phosphorescent compound or a compound other than a phosphorescent compound.

The relationship among the ionization potentials of the compounds having the largest ionization potentials of the respective layers is described below with reference to the drawings.

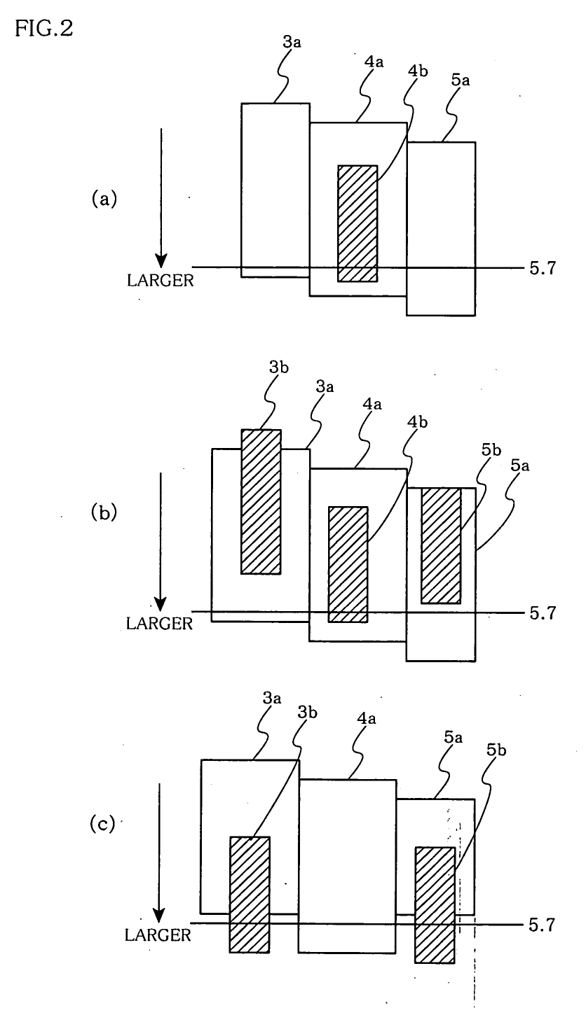

FIGS. 2(a) to 2(c) are views showing examples of the energy levels of the compounds forming the first layer 3, the second layer 4, and the third layer 5. In FIGS. 2(a) to 2(c), the level on the upper side indicates the LUMO level (affinity level: Af) of the compound, and the level on the lower side indicates the HOMO level (ionization potential: Ip) of the compound.

In FIG. 2(a), the first layer 3 is formed of a compound 3a. The compound 3a is a compound other than a phosphorescent compound. The compound 3a is the compound forming the first layer 3 which has the largest ionization-potential.

The second layer 4 is formed of a compound 4a and a compound 4b. The compound 4a is a compound other than a phosphorescent compound, and the compound 4b is a phosphorescent compound. The compound 4a is the compound forming the second layer 4 which has the largest ionization potential.

The third layer 5 is formed of a compound 5a. The compound 5a is a compound other than a phosphorescent compound. The compound 5a is the compound forming the third layer 5 which has the largest ionization potential.

In this example, the compounds 3a, 4a, and 5a have an ionization potential of 5.7 eV or more and differ in the ionization potential in an amount of less than 1.0 eV.

In FIG. 2(b), the first layer 3 is formed of the compound 3a and a compound 3.b. The compound 3a is a compound other than a phosphorescent compound, and the compound 3b is a phosphorescent compound. The compound 3a is the compound forming the first layer 3 which has the largest ionization potential.

The second layer 4 is formed of the compound 4a and the compound 4b. The compound 4a is a compound other than a phosphorescent compound, and the compound 4b is a phosphorescent compound. The compound 4a is the compound forming the second layer 4 which has the largest ionization potential.

The third layer 5 is formed of the compound 5a and a compound 5b. The compound 5a is a compound other than a phosphorescent compound, and the compound 5b is a phosphorescent compound. The compound 5a is the compound forming the third layer 5 which has the largest ionization potential.

In this example, the compounds 3a, 4a, and 5a have an ionization potential of 5.7 eV or more and differ in the ionization potential in an amount of less than 1.0 eV.

In FIG. 2(c), the first layer 3 is formed of the compound 3a and the compound 3b. The compound 3a is a compound other than a phosphorescent compound, and the compound 3b is a phosphorescent compound. The compound 3b is the compound forming the first layer 3 which has the largest ionization potential.

The second layer 4 is formed of the compound 4a. The compound 4a is a compound other than a phosphorescent compound. The compound 4a is the compound forming the second layer 4 which has the largest ionization potential.

The third layer 5 is formed of the compound 5a and the compound 5b. The compound 5a is a compound other than a phosphorescent compound, and the compound 5b is a phosphorescent compound. The compound 5b is the compound forming the third layer 5 which has the largest ionization potential.

In this example, the compounds 3b, 4a, and 5b have an ionization potential of 5.7 eV or more and differ in the ionization potential in an amount of less than 1.0 eV.

The compounds having the largest ionization potentials of the respective layers are preferably compounds other than a phosphorescent compound. Accordingly, the examples in FIGS. 2(a) and 2(c) are preferable among the examples in FIGS. 2(a) to 2(b).

The compounds having the largest ionization potentials of the respective layers differ in the ionization potential in an amount of less than 1.0 eV, preferably less than 0.6 eV, and still more preferably less than 0.4 eV.

When the ionization potentials satisfy such a relationship, the organic EL device 1 exhibits a high efficiency.

The ionization potential of the compound having the largest ionization potential of the second layer 4 is preferably equal to or greater than the ionization potential of the compound having the largest ionization potential of the first layer 3.

The ionization potential of the compound having the largest ionization potential of the third layer 5 is preferably equal to or greater than the ionization potential of the compound having the largest ionization potential of the second layer 4.

It is preferable that at least two of the compounds respectively forming the first layer 3, the second layer 4, and the third layer 5 be compounds other than a phosphorescent compound and have a singlet energy level of 3.3 eV or more.

These compounds are preferably compounds having the largest ionization potentials of the respective layers.

It is preferable that at least two of the compounds respectively forming the first layer 3, the second layer 4, and the third layer 5 be compounds other than a phosphorescent compound and have a lowest triplet energy level of 2.7 eV or more, and preferably 2.8 eV or more.

These compounds are preferably compounds having the largest ionization potentials of the respective layers.

The lowest triplet energy level of the phosphorescent compound is preferably 2.4 eV or more.

The organic EL device according to the invention has a devise structure in which three or more layers are stacked between the electrodes. The following structures can be given as examples of the device structure.

1. Anode, hole transporting layer, electron blocking layer, emitting layer, electron transporting layer, and cathode

2. Anode, hole transporting layer, emitting layer, hole blocking layer, electron transporting layer, and cathode

3. Anode, hole injecting layer, hole transporting layer, emitting layer, electron transporting layer, electron injecting layer, and cathode

4. Anode, hole transporting layer, electron blocking layer, emitting layer, electron transporting layer, electron injecting layer, and cathode

5. Anode, hole transporting layer, emitting layer, emitting layer, and cathode

6. Anode, emitting layer, emitting layer, electron transporting layer, and cathode

7. Anode, hole transporting layer, emitting layer, emitting layer, electron transporting layer, and cathode

8. Anode, hole transporting layer, electron blocking layer, emitting layer, and cathode

9. Anode, emitting layer, electron transporting layer, electron injecting layer, and cathode

Each member of the organic EL device according to the invention is described below in detail.

The emitting layer has a function of allowing injection of holes from the anode or the hole injecting layer upon application of an electric field, a function of allowing injection of electrons from the cathode or the electron injecting layer, a function of allowing the injected carriers (electrons and holes) to move due to the force of the electric field, and a function of allowing the electrons and the holes to recombine to emit light. The emitting layer of the organic EL device according to the invention preferably includes at least a phosphorescent compound, and still more preferably includes a host compound of which the guest compound is the phosphorescent compound.

The phosphorescent compound is not particularly limited insofar as the phosphorescent compound emits phosphorescence in the temperature range in which the device operates. It is preferable to select a compound with a lowest triplet energy level of 2.4 eV or more. It is preferable to select a heavy metal complex having a carbazole derivative, a pyridine derivative, a pyrimidine derivative, a triazine derivative, an indole derivative, a metaphenylene derivative, an arylamine derivative, or a combined structure of these derivatives. As specific examples of the heavy metal complex, heavy metal complexes such as Ir, Pd, Cu, Au, Pt, Rh, Re, and Os complexes can be given. Of these, Ir and Pt complexes are preferable.

Specific examples are given below. 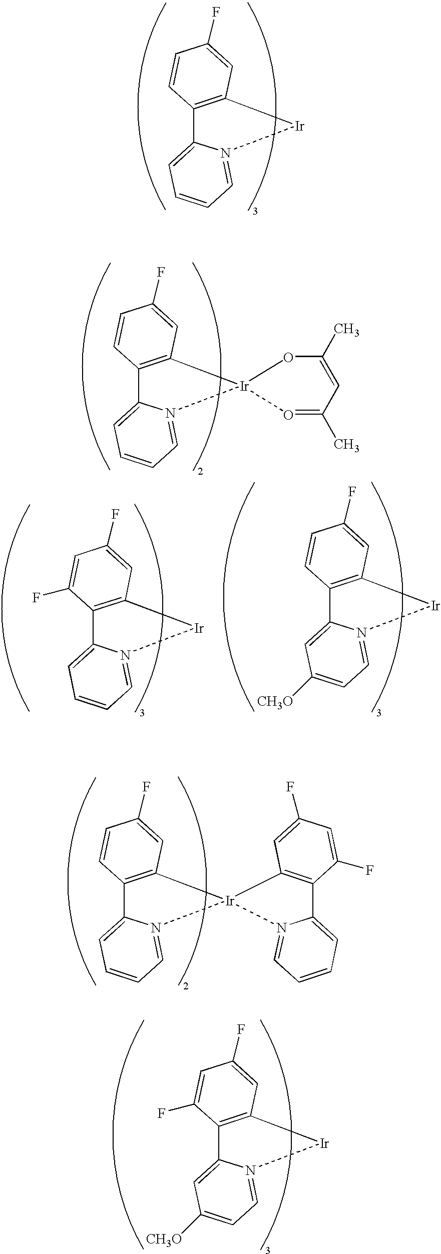 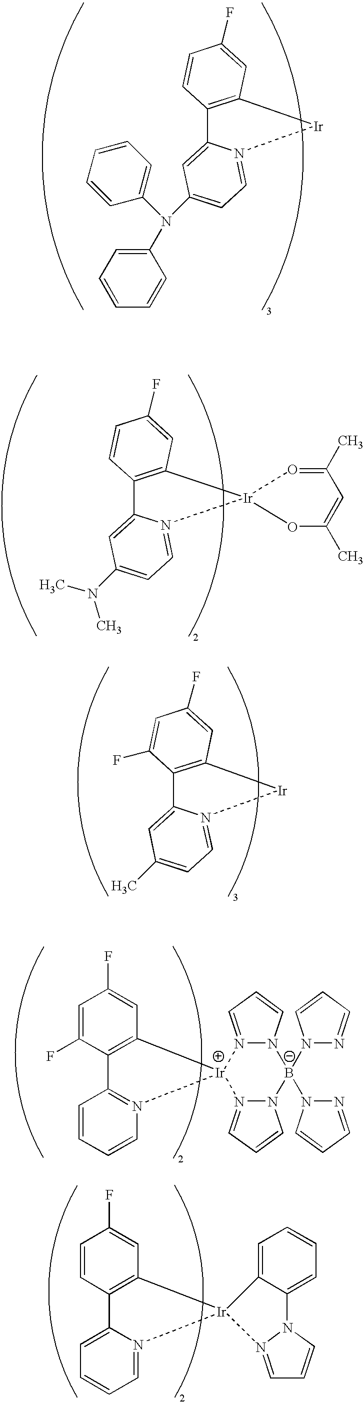 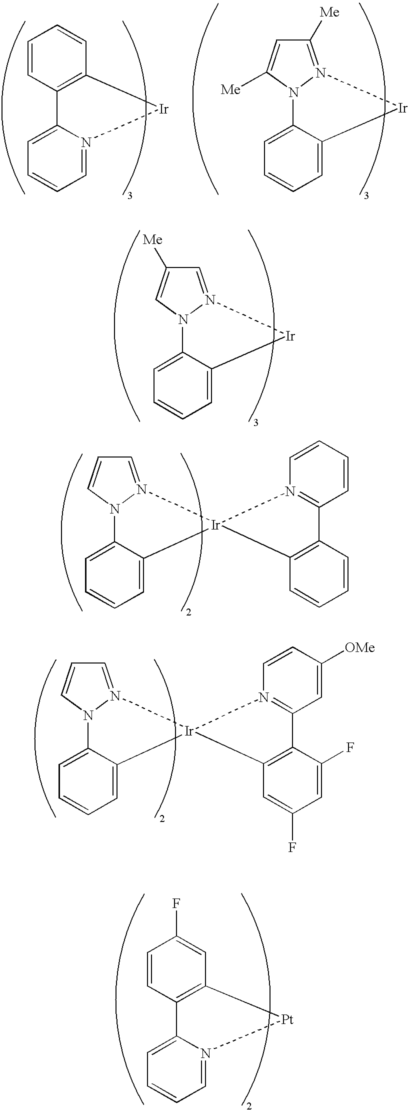
wherein Me indicates a methyl group.

As examples of the host compound, a compound having a carbazole skeleton, a compound having a diarylamine skeleton, a compound having a pyridine skeleton, a compound having a pyrazine skeleton, a compound having a triazine skeleton, a compound having an arylsilane skeleton, and the like can be given. It is preferable that the T₁ level (energy level in the lowest triplet excited state) of the host compound be greater than the T₁ level of the guest compound. The host compound may be a low-molecular-weight compound or a high-molecular-weight compound.

The emitting layer is formed by codepositing the host compound and the phosphorescent compound, for example. This allows formation of an emitting layer in which the phosphorescent compound is doped with the host compound.

The anode supplies holes to the hole injecting layer, the hole transporting layer, the emitting layer, and the like. It is effective that the anode have a work function of 4.5 eV or more. As a compound for forming the anode, a metal, alloy, metal oxide, conductive compound, a mixture of these materials, or the like may be used. As specific examples of the compound for forming the anode, conductive metal oxides such as tin oxide, zinc oxide, indium oxide, and tin-doped indium oxide (ITO); metals such as gold, silver, chromium, and nickel; a mixture or a stacked product of the conductive metal oxide and the metal; inorganic conductive substances such as copper iodide and copper sulfide; organic conductive materials such as polyaniline, polythiophene, and polypyrrole; a stacked product of the conductive material and ITO, and the like can be given. Of these, the conductive metal oxide is preferable. In particular, it is preferable to use ITO from the viewpoint of productivity, conductivity, transparency, and the like. The thickness of the anode may be appropriately selected depending on the material.

The cathode supplies electrons to the electron injecting layer, the electron transporting layer, the emitting layer, and the like. As a compound for forming the cathode, a metal, alloy, metal halide, metal oxide, conductive compound, or a mixture of these materials may be used. As specific examples of the compound used for the cathode, alkali metals (e.g. Li, Na, and K) and fluorides or oxides thereof, alkaline earth metals (e.g. Mg and Ca) and fluorides or oxides thereof, gold, silver, lead, aluminum, sodium-potassium alloy or sodium-potassium mixed metal, lithium-aluminum alloy or lithium-aluminum mixed metal, magnesium-silver alloy or magnesium-silver mixed metal, rare earth metals such as indium and ytterbium, and the like can be given. Of these, aluminum, lithium-aluminum alloy or lithium-aluminum mixed metal, magnesium-silver alloy or magnesium-silver mixed metal, and the like are preferable. The cathode may have a single-layer structure formed of the above compound, or may have a stacked structure including a layer formed of the above compound. For example, a stacked structure of aluminum/lithium fluoride or aluminum/lithium oxide is preferable. The thickness of the cathode may be appropriately selected depending on the compound used.

The hole injecting layer and the hole transporting layer are not limited insofar as these layers have one of a function of injecting holes from the anode, a function of transporting holes, and a function of blocking electrons injected from the cathode. As specific examples of the material for the hole injecting layer and the hole transporting layer, a carbazole derivative, triazole derivative, oxazole derivative, oxadiazole derivative, imidazole derivative, polyarylalkane derivative, pyrazoline derivative, pyrazolone derivative, phenylenediamine derivative, arylamine derivative, amino-substituted chalcone derivative, styrylanthracene derivative, fluorenone derivative, hydrazone derivative, stilbene derivative, silazane derivative, aromatic tertiary amine compound, styrylamine compound, aromatic dimethylidyne compound, porphyrin compound, polysilane compound, poly(N-vinylcarbazole) derivative, aniline copolymer, conductive high-molecular-weight oligomer such as a thiophene oligomer and polythiophene, organosilane derivative, and the like can be given. The hole injecting layer and the hole transporting layer may have a single-layer structure formed of one, or two or more of the above materials, or may have a multilayer structure formed of a plurality of layers of the same composition or different compositions.

The electron injecting layer and the electron transporting layer are not limited insofar as these layers have one of a function of injecting electrons from the cathode, a function of transporting electrons, and a function of blocking holes injected from the anode. As specific examples of the material for the electron injecting layer and the electron transporting layer, a triazole derivative, oxazole derivative, oxadiazole derivative, imidazole derivative, carbazole derivative, fluorenone derivative, anthraquinodimethane derivative, anthrone derivative, diphenylquinone derivative, thiopyran dioxide derivative, carbodiimide derivative, fluorenylidenemethane derivative, distyrylpyrazine derivative, aromatic tetracarboxylic anhydride such as naphthalene and perylene, metal complexes such as metal complexes of a phthalocyanine derivative and 8-quinolinol derivative and metal complexes having metal phthalocyanine, benzoxazole, or benzothiazole as the ligand, organosilane derivative, and the like can be given. The electron injecting layer and the electron transporting layer may have a single-layer structure formed of one, or two or more of the above compounds, or may have a multilayer structure formed of a plurality of layers of the same composition or different compositions.

It is preferable that the compound forming the electron injecting layer and/or the electron transporting layer have a π electron deficient nitrogen-containing hetero ring in the molecular skeleton.

As preferred examples of the π electron deficient nitrogen-containing hetero ring derivative, a derivative of a nitrogen-containing five-membered ring selected from a benzimidazole ring, benzotriazole ring, pyridinoimidazole ring, pyrimidinoimidazole ring, and pyridazinoimidazole ring, and a nitrogen-containing six-membered ring derivative formed of a pyridine ring, pyrimidine ring, pyrazine ring, or triazine ring can be given.

It is preferable to use an insulator or semiconductor inorganic compound as the material forming the electron injecting layer and/or the electron transporting layer. If the electron injecting layer and/or the electron transporting layer is formed of an insulator or a semiconductor, the electron injecting properties can be improved by effectively preventing leakage of current.

As such an insulator, it is preferable to use at least one metal compound selected from the group consisting of an alkali metal chalcogenide, alkaline earth metal chalcogenide, alkali metal halide, and alkaline earth metal halide. If the electron injecting layer or the electron transporting layer is formed of an alkali metal chalcogenide or the like, the electron injecting properties can be further improved.

As preferred examples of the alkali metal chalcogenide, Li₂O, Na₂S, Na₂Se, and Na₂O can be given. As preferred examples of the alkaline earth metal chalcogenide, CaO, BaO, SrO, BeO, BaS, and CaSe can be given. As preferred examples of the alkali metal halide, LiF, NaF, KF, LiC₁, KC₁, and NaCl can be given. As examples of the alkaline earth metal halide, fluorides such as CaF₂, BaF₂, SrF₂, MgF₂, and BeF₂ and halides other than the fluorides can be given.

As examples of the semiconductor forming the electron injecting layer and the electron transporting layer, a single material or a combination of two or more of an oxide, nitride, or oxynitride containing at least one element selected from Ba, Ca, Sr, Yb, Al, Ga, In, Li, Na, Cd, Mg, Si, Ta, Sb, and Zn, and the like can be given.

It is preferable that the inorganic compound forming the electron transporting layer be a microcrystalline or amorphous insulating thin film. If the electron transporting layer is formed of such an insulating thin film, a more uniform thin film is formed, whereby pixel defects such as dark spots can be reduced. As examples of such an inorganic compound, the above-mentioned alkali metal chalcogenide, alkaline earth metal chalcogenide, alkali metal halide, and alkaline earth metal halide can be given.

In the organic EL device according to the invention, the electron injecting layer and/or the electron transporting layer may include a reductive dopant with a work function of 2.9 eV or less. In the invention, the reductive dopant is a compound which increases electron injecting efficiency.

In the invention, it is preferable that the reductive dopant be added to the interfacial region between the cathode and the organic thin film layer so that the reductive dopant reduces at least a part of the organic layer contained in the interfacial region to produce anions. A preferred reductive dopant is at least one compound selected from the group consisting of an alkali metal, alkaline earth metal, rare earth metal; oxides of an alkali metal, alkaline earth metal, and rare earth metal; halides of an alkali metal, alkaline earth metal, and rare earth metal; and an alkali metal complex, alkaline earth metal complex, and rare earth metal complex.

A preferred reductive dopant is at least one alkali metal selected from the group consisting of Na (work function: 2.36 eV), K (work function: 2.28 eV), Rb (work function: 2.16 eV), and Cs (work function: 1.95 eV); or at least one alkaline earth metal selected from the group consisting of Ca (work function: 2.9 eV), Sr (work function: 2.0 to 2.5 eV), and Ba (work function: 2.52 eV).

The reductive dopant is more preferably at least one alkali metal selected from the group consisting of K, Rb, and Cs, more preferably Rb or Cs, and most preferably Cs. These alkali metals exhibit a particularly high reducing capability so that an increase in the luminance and the lifetime of the organic EL device can be achieved by adding a relatively small amount of alkali metal to the electron injection region.

As the alkaline earth metal oxide, BaO, SrO, CaO, BaₓSr₁₋ₓO (0<x<1)₁ and BaₓCa₁₋ₓO (0<x<1) are preferable.

As examples of the alkali oxide or alkali fluoride, LiF, Li₂O, NaF, and the like can be given.

The alkali metal complex, alkaline earth metal complex, and rare earth metal complex are not particularly limited insofar as the complex contains at least one of an alkali metal ion, alkaline earth metal ion, and rare earth metal ion as the metal ion. As examples of the ligand, quinolinol, benzoquinolinol, acridinol, phenanthridinol, hydroxyphenyloxazole, hydroxyphenylthiazole, hydroxydiaryloxadiazole, hydroxydiarylthiadiazole, hydroxyphenylpyridine, hydroxyphenylbenzimidazole, hydroxybenzotriazole, hydroxyfurborane, bipyridyl, phenanthroline, phthalocyanine, porphyrin, cyclopentadiene, β-diketone, azomethine, derivatives thereof, and the like can be given. Note that the ligand is not limited thereto.

The reductive dopant is preferably formed in the shape of a layer or islands. The thickness of the reductive dopant is preferably 0.05 to 8 nm when used in the shape of a layer.

As the method of forming the electron injecting layer and/or the electron transporting layer containing the reductive dopant, a method is preferable in which a compound which is the 0.5 emitting compound or the electron injecting compound which forms the interfacial region is deposited while depositing the reductive dopant by resistance heating deposition to disperse the reductive dopant in the compound. The dispersion concentration (molar ratio) is usually 100:1 to 1:100, and preferably 5:1 to 1:5. When forming the reductive dopant in the shape of a layer, the emitting compound or the electron injecting compound which is the organic-layer at the interface is formed in the shape of a layer, and the reductive dopant is deposited by resistance heating deposition to a thickness of preferably 0.5 to 15 nm. When forming the reductive dopant in the shape of islands, after forming the emitting compound or the electron injecting compound which is the organic layer at the interface, the reductive dopant is deposited by resistance heating deposition to a thickness of preferably 0.05 to 1 nm.

In the organic EL device according to the invention, the formation method for each layer is not particularly limited. Various methods may be utilized such as vacuum evaporation, LB method, resistance heating deposition, electron beam method, sputtering, molecular stack method, coating (spin coating, casting, and dip coating), inkjet method, and printing.

An organic thin film layer including a phosphorescent material (metal complex compound) may be formed using a known method such as vacuum deposition, molecular beam epitaxy (MBE), or a coating method using a solution in which the material is dissolved in a solvent, such as dipping, spin coating, casting, bar coating, or roll coating.

In the above coating method, the metal complex compound is dissolved in a solvent to prepare a coating liquid, and the coating liquid is applied to and dried on a desired layer. A resin may be added to the coating liquid. The resin may be dissolved or dispersed in the solvent. As the resin, a non-conjugated polymer (e.g. polyvinylcarbazole) or a conjugated polymer (e.g. polyolefin polymer) may be used. As specific examples of the resin, polyvinyl chloride, polycarbonate, polystyrene, polymethyl methacrylate, polybutyl methacrylate, polyester, polysulfone, polyphenylene oxide, polybutadiene, poly(N-vinylcarbazole), hydrocarbon resin, ketone resin, phenoxy resin, polyamide, ethyl cellulose, vinyl acetate, ABS resin, polyurethane, melamine resin, unsaturated polyester resin, alkyd resin, epoxy resin, silicon resin, and the like can be given.

The thickness of each organic layer of the organic EL device according to the invention is not particularly limited. In general, defects such as pinholes tend to occur when the thickness is too small, and a high voltage must be applied when the thickness is too great, resulting in poor efficiency. Therefore, the thickness of each organic layer is preferably several nanometers to 1 micron.

### EXAMPLES

Compounds of the following formulas were used in the examples and comparative examples. The characteristics of these compounds were measured using the following methods. The results are shown in Table 1. 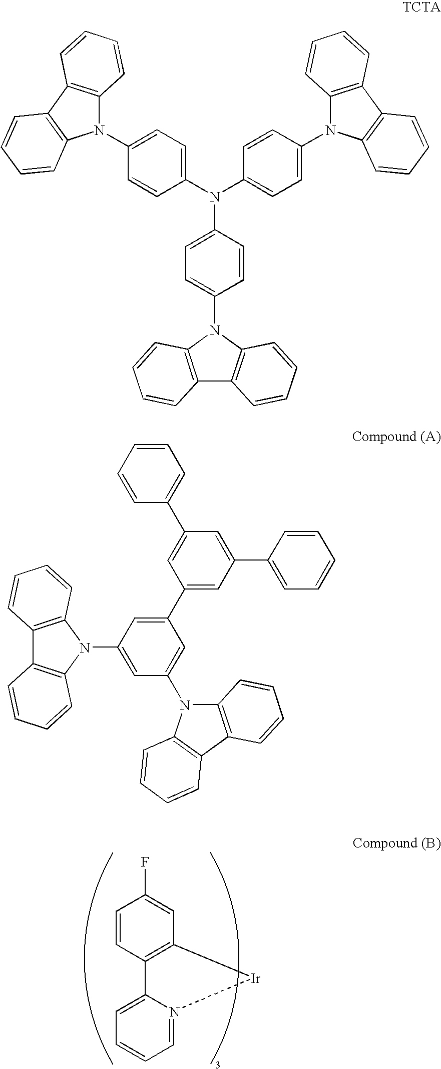 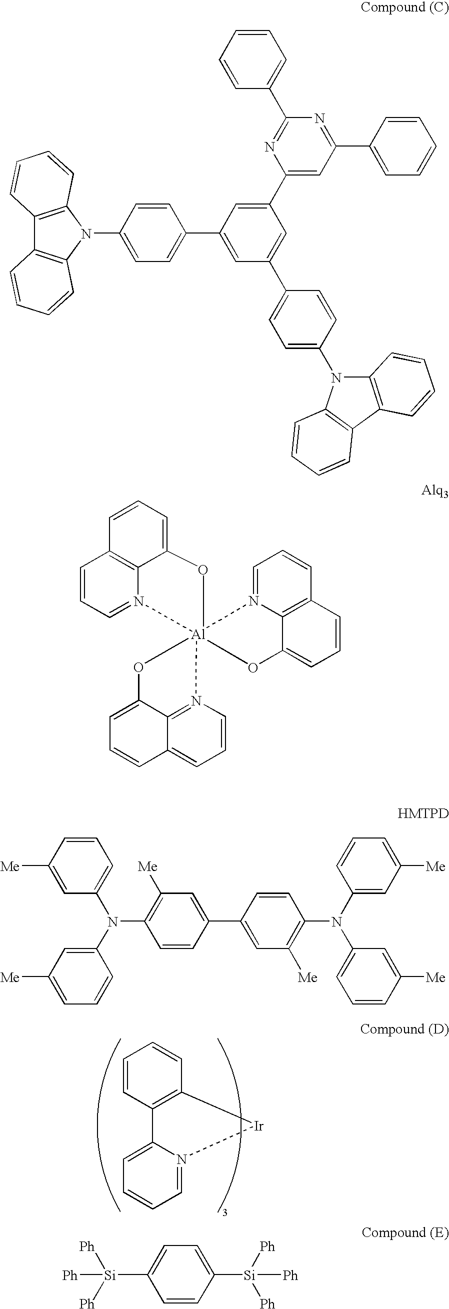 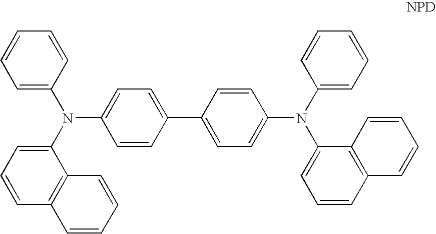
(1) Ionization Potential

A thin film of each compound was formed, and the ionization potential of the thin film was measured using “AC-1” manufactured by Riken Keiki Co., Ltd.

A glass substrate was subjected to ultrasonic cleaning for five minutes in isopropyl alcohol, five minutes in water, and five minutes in isopropyl alcohol, and then subjected to UV cleaning for 30 minutes. A thin film sample of the measurement target compound was formed on the glass substrate using a vacuum deposition device. The film was formed to a thickness of 2000 angstroms using “SGC-8MII” manufactured by Showa Shinku Co., Ltd. at a final vacuum of 5.3×10⁻⁴ Pa or less and a deposition rate of 2 angstroms/sec.

The ionization potential was measured using an atmospheric photoelectron spectrometer (“AC-1” manufactured by Riken Keiki Co., Ltd.). Light obtained by dispersing ultraviolet rays from a deuterium lamp using a spectroscope was applied to the thin film sample, and the emitted photoelectrons were measured using an open counter. The intersection of the background and the square root of the quantum yield in the photoelectron spectrum in which the square root of the quantum yield was plotted along the vertical axis and the energy of applied light was plotted along the horizontal axis was taken as the ionization potential.

(2) Singlet Energy Level

The compound was dissolved in toluene to obtain a 10⁻⁵ mol/l solution. The absorption spectrum was measured using a spectro-photometer (“U3410” manufactured by Hitachi, Ltd.). A line tangent to the UV absorption spectrum was drawn at the rising edge on the longer wavelength side, and the wavelength (absorption edge) at which the tangent line intersects the horizontal axis was determined. This wavelength was converted into an energy value to determine the energy level.

(3) Lowest Triplet Energy Level

The lowest triplet energy level T₁ was measured as follows. The lowest triplet energy level T₁ was measured using Fluorolog II manufactured by SPEX at a concentration of 10 micromol/l and a temperature of 77° K using EPA (diethyl ether: isopentane: isopropyl alcohol=5:5:2 (volume ratio)) as a solvent utilizing a quartz cell. A line tangent to the resulting phosphorescence spectrum was drawn at the rising edge on the shorter wavelength side, and the wavelength (absorption edge) at which the tangent line intersects the horizontal axis was determined. This wavelength was converted into an energy value.

### Example 1

A glass substrate with an ITO transparent electrode (25 mm×75 mm×0.7 mm) was subjected to ultrasonic cleaning in isopropyl alcohol for five minutes and then subjected to UV ozone cleaning for 30 minutes. The cleaned glass substrate with the transparent electrode was installed in a substrate holder of a vacuum deposition device, and a TCTA film with a thickness of 95 nm was formed on the surface of the glass substrate on which the transparent electrode was formed so that the transparent electrode was covered with the TCTA film. The TCTA film functions as a hole injecting layer. The compound (A) was deposited on the TCTA film as a host compound to a thickness of 30 nm to form an emitting layer. The Ir metal complex compound (B) was added as a phosphorescent Ir metal complex dopant. The concentration of the metal complex compound (B) in the emitting layer was adjusted to 7.5 wt %. This film functions as an emitting layer. The compound (C) was formed on this film to a thickness of 25 nm. This film functions as an electron transporting layer. An Alq₃ film was formed on this film to a thickness of 5 nm. This film functions as an electron transporting layer. Lithium fluoride was then deposited to a thickness of 0.1 nm, and aluminum was deposited to a thickness of 150 nm. This Al/LiF film functions as a cathode. An organic EL device was thus fabricated.

After sealing the resulting device, electricity was supplied to the device for test. Blue green light with a luminance of 124 cd/m² was obtained at a voltage of 5.5 V and a current density of 0.43 mA/cm². The luminous efficiency was 30 cd/A. The device was driven at a constant current and an initial luminance of 200 cd/m². The period of time until the luminance was halved to 100 cd/m² was measured and found to be 1700 hours.

### Example 2

An organic EL device was fabricated in the same manner as in Example 1 except for using the compound (D) instead of the compound (B). After sealing the resulting device, electricity was supplied to the device for test in the same manner as in Example 1.

Green light with a luminance of 110 cd/m² was obtained at a voltage of 5.6 V and a current density of 0.16 mA/cm². The luminous efficiency was 69 cd/A. The device was driven at a constant current and an initial luminance of 1500 cd/m². The period of time until the luminance was halved to 750 cd/m² was measured and found to be 3680 hours.

### Comparative Example 1

An organic EL device was fabricated in the same manner as in Example 1 except for using HMTPD instead of TCTA.

After sealing the resulting device, electricity was supplied to the device in the same manner as in Example 1.

Blue green light with a luminance of 104 cd/m² was obtained at a voltage of 7.5 V and a current density of 0.98 mA/cm². The luminous efficiency was 11 cd/A. The device was driven at a constant current and an initial luminance of 200 cd/m². The period of time until the luminance was halved to 100 cd/m² was measured and found to be 285 hours.

### Comparative Example 2

An organic EL device was fabricated in the same manner as in Example 1 except for using NPD instead of TCTA.

After sealing the resulting device, electricity was supplied to the device in the same manner as in Example 1.

Blue green light with a luminance of 100 cd/m² was obtained at a voltage of 7.2 V and a current density of 1.54 mA/cm². The luminous efficiency was 6 cd/A. The device was driven at a constant current and an initial luminance of 200 cd/m². The period of time until the luminance was halved to 100 cd/m² was measured and found to be 410 hours.

### Comparative Example 3

An organic EL device was fabricated in the same manner as in Example 1 except for using the compound (E) instead of the compound (A).

After sealing the resulting device, electricity was supplied to the device in the same manner as in Example 1.

Blue green light with a luminance of 100 cd/m² was obtained at a voltage of 8.4 V and a current density of 1.88 mA/cm². The luminous efficiency was 5 cd/A. The device was driven at a constant current and an initial luminance of 200 cd/m². The period of time until the luminance was halved to 100 cd/m² was measured and found to be 165 hours.

### Comparative Example 4

An organic EL device was fabricated in the same manner as in Example 2 except for using the compound (E) instead of the compound (A).

After sealing the resulting device, electricity was supplied to the device in the same manner as in Example 1.

Green light with a luminance of 100 cd/m² was obtained at a voltage of 7.8 V and a current density of 0.65 mA/cm². The luminous efficiency was 15 cd/A. The device was driven at a constant current and an initial luminance of 1500 cd/m². The period of time until the luminance was halved to 750 cd/m² was measured and found to be 1210 hours.

TABLE 1

| | Hole transporting layer | | | | Emitting layer | | | |
|---|---|---|---|---|---|---|---|---|
| | | Ionization | Singlet | Lowest triplet | | Ionization | Singlet | Lowest triplet |
| | | potential | energy level | energy level | | potential | energy level | energy level |
| | Compound | (eV) | (eV) | (eV) | Compound | (eV) | (eV) | (eV) |
| Example 1 | TCTA | 5.8 | 3.3 | 2.9 | (A) | 6.0 | 3.6 | 2.9 |
| | | | | | (B) | 5.7 | — | 2.6 |
| Example 2 | TCTA | 5.8 | 3.3 | 2.9 | (A) | 6.0 | 3.6 | 2.9 |
| | | | | | (D) | 5.3 | — | 2.4 |
| Comparative | HMTPD | 5.6 | 3.3 | 2.6 | (A) | 6.0 | 3.6 | 2.9 |
| Example 1 | | | | | (B) | 5.7 | — | 2.6 |
| Comparative | NPD | 5.5 | 3.0 | 2.4 | (A) | 6.0 | 3.6 | 2.9 |
| Example 2 | | | | | (B) | 5.7 | — | 2.6 |
| Comparative | TCTA | 5.8 | 3.3 | 2.9 | (E) | 7.1 | 4.3 | 3.5 |
| Example 3 | | | | | (B) | 5.7 | — | 2.6 |
| Comparative | TCTA | 5.8 | 3.3 | 2.9 | (E) | 7.1 | 4.3 | 3.5 |
| Example 4 | | | | | (D) | 5.3 | — | 2.6 |

| | Electron transporting layer | | | |
|---|---|---|---|---|
| | | Ionization | Singlet | Lowest triplet |
| | | potential | energy level | energy level |
| | Compound | (eV) | (eV) | (eV) |
| Example 1 | (C) | 6.0 | 3.9 | 2.9 |
| | Alq₃ | 5.8 | 2.7 | — |
| Example 2 | (C) | 6.0 | 3.9 | 2.9 |
| | Alq₃ | 5.8 | 2.7 | — |
| Comparative | (C) | 6.0 | 3.9 | 2.9 |
| Example 1 | Alq₃ | 5.8 | 2.7 | — |
| Comparative | (C) | 6.0 | 3.9 | 2.9 |
| Example 2 | Alq₃ | 5.8 | 2.7 | — |
| Comparative | (C) | 6.0 | 3.9 | 2.9 |
| Example 3 | Alq₃ | 5.8 | 2.7 | — |
| Comparative | (C) | 6.0 | 3.9 | 2.9 |
| Example 4 | Alq₃ | 5.8 | 2.7 | — |

TABLE 2

| | | | | Luminous | | |
|---|---|---|---|---|---|---|
| | Voltage | Current density | Luminance | efficiency | Initial luminance | Half life |
| | (V) | (mA/cm²) | (cd/m²) | (cd/A) | (cd/m²) | (h) |
| Example 1 | 5.5 | 0.43 | 124 | 30 | 200 | 1700 |
| Example 2 | 5.6 | 0.16 | 110 | 69 | 1500 | 3680 |
| Comparative | 7.5 | 0.98 | 104 | 11 | 200 | 285 |
| Example 1 | | | | | | |
| Comparative | 7.2 | 1.54 | 100 | 6 | 200 | 410 |
| Example 2 | | | | | | |
| Comparative | 8.4 | 1.88 | 100 | 5 | 200 | 165 |
| Example 3 | | | | | | |
| Comparative | 7.8 | 0.65 | 100 | 15 | 1500 | 1210 |
| Example 4 | | | | | | |

As shown in Table 2, the organic EL devices of Examples 1 to 2 are driven at a low voltage and exhibit a high luminous efficiency and a long lifetime in comparison with the organic EL devices of Comparative Examples 1 to 4.

### INDUSTRIAL APPLICABILITY

As described above in detail, the organic EL device according to the invention exhibits a high luminous efficiency and a long lifetime, may be used as an organic EL material of each color such as blue, may be applied in the fields of a display element, display, backlight, illumination light source, sign, signboard, interior, and the like, and is particularly suitable as a display element for a color display.

What is claimed is:

1. An organic electroluminescent device comprising:
an anode, a cathode, and at least a first layer, a second layer, and a third layer provided between the anode and the cathode;
at least one of the first to third layers including a phosphorescent compound, at least one of the first to third layers being an emitting layer, and compounds respectively forming the first to third layers and having the largest ionization potentials of the respective layers having an ionization potential of 5.7 eV or more and differing in the ionization potential in an amount of less than 1.0 eV.

2. The organic electroluminescent device according to claim 1, wherein the compounds having the largest ionization potentials of the respective layers are compounds other than the phosphorescent compound.

3. The organic electroluminescent device according to claim 1, wherein at least one of the first to third layers is the emitting layer, and at least one emitting layer includes the phosphorescent compound.

4. The organic electroluminescent device according to claim 1, wherein the second layer is the emitting layer, and the emitting layer includes the phosphorescent compound.

5. The organic electroluminescent device according to claim 1, wherein the difference in the ionization potential is less than 0.6 eV.

6. The organic electroluminescent device according to claim 1, wherein at least two of a first compound forming the first layer, a second compound forming the second layer, and a third compound forming the third layer are compounds other than the phosphorescent compound and have a singlet energy level of 3.3 eV or more.

7. The organic electroluminescent device according to claim 1, wherein at least two of a first compound forming the first layer, a second compound forming the second layer, and a third compound forming the third layer are compounds other than the phosphorescent compound and have a lowest triplet energy level of 2.7 eV or more.

8. The organic electroluminescent device according to claim 1, wherein the phosphorescent compound has a lowest triplet energy level of 2.4 eV or more.

9. The organic electroluminescent device according to claim 4, wherein the first layer and the third layer contact the emitting layer including the phosphorescent compound.

10. The organic electroluminescent device according to claim 1, wherein the phosphorescent compound is a heavy metal complex.
